(19) United States
(12) Patent Application Publication
(10) Pub. No.: US 2014/0117557 A1
(43) Pub. Date: May 1, 2014

(54) PACKAGE SUBSTRATE AND METHOD OF FORMING THE SAME

(71) Applicants: UNIMICRON TECHNOLOGY CORPORATION, Taoyuan (TW); INDUSTRIAL TECHNOLOGY RESEARCH INSTITUTE, Hsinchu (TW)

(72) Inventors: Yu-Hua CHEN, Hsinchu (TW); Wei-Chung LO, Hsinchu (TW); Dyi-Chung HU, Taoyuan (TW); Chang-Hong HSIEH, Taoyuan (TW)

(73) Assignees: UNIMICRON TECHNOLOGY CORPORATION, Taoyuan (TW); INDUSTRIAL TECHNOLOGY RESEARCH INSTITUTE, Hsinchu (TW)

(21) Appl. No.: 13/966,045

(22) Filed: Aug. 13, 2013

(30) Foreign Application Priority Data
Oct. 25, 2012 (TW) 101139429

(51) Int. Cl. H01L 23/48; H01L 21/56

(52) U.S. Cl. CPC H01L 23/481; H01L 21/56
USPC 257/774; 438/124

(57) ABSTRACT

A package substrate and a method for forming the package substrate are disclosed. The package substrate includes an interposer having a plurality of conductive through vias and a first insulating layer formed on the sidewalls of the conductive through vias, a second insulating layer formed on one side of the interposer, and a plurality of conductive vias formed in the second insulating layer and electrically connected to the conductive through vias. By increasing the thickness of the first insulating layer, the face diameter of the conductive through vias can be reduced, and the layout density of the conductive through vias in the interposer can thus be increased.

### CROSS-REFERENCE TO RELATED APPLICATIONS

This application claims priority to Taiwanese Patent Application No. 101139429, filed on Oct. 25, 2012. The entirety of the above-mentioned patent application is hereby incorporated by reference herein and made a part of this specification.

### FIELD

The present disclosure relates to a package substrate, and relates to a package substrate embedded with an interposer and a method for forming the package substrate.

### BACKGROUND

As the demands for more compact and more multi-functional electronic products increase, layout density on chips has increased to nano-scale, and space between contacts on the chips becomes extremely small. However, the size of space between electrical contacts of current flip-chip package substrates is in the micron level, and cannot be reduced to accommodate the size of space between contacts on the chips. As such, despite that semiconductor wafers with high line densities are available, there are no accommodating package substrates, so that electronic products cannot be effectively produced.

In order to overcome the above problem, a silicon interposer is added between a package substrate and a semiconductor chip, wherein conductive through-silicon vias (TSVs) made of metals are used for electrical and signal transmission. A redistribution layer (RDL) is formed on the silicon interposer, so that one side of the silicon interposer is electrically connected to contacts with wider space therebetween of the package substrate through conductive bumps joined at the ends of the conductive TSVs, and the other side of the silicon interposer is connected to contacts with narrower space therebetween on the chip through electrical connecting pads through the topmost layer of the RDL. Thus, the package substrate can be connected to the chip having higher-density contacts.

### SUMMARY

The present disclosure provides a package substrate having an interposer embedded therein. The thickness of an insulating layer outside conductive through vias in the interposer is increased, such that the face diameter formed by the conductive through vias and the insulating layer is greater than 80 μm, and the face diameter of the conductive through vias is not greater than 80 μm.

The present disclosure provides a package substrate having an interposer including a first side, a second side opposing the first side, and at least one conductive through via penetrating from the first side to the second side, wherein a redistribution layer is formed on the first side of the interposer and electrically connected to the conductive through via, a first insulating layer is formed on sidewall of the conductive through via, and wherein a face diameter of the conductive through via is not greater than 80 μm, and a face diameter formed by the conductive through via and the first insulating layer is greater than 80 μm; a second insulating layer formed on the second side of the interposer; and at least one conductive via formed in the second insulating layer and electrically connected to the conductive through via.

Since the face diameter of the conductive through vias is not greater than 80 μm, the layout density of the conductive through vias in the interposer is increased.

Furthermore, since the face diameter formed by the conductive through vias and the insulating layer is greater than 80 μm, laser apertures are easily aligned, and the vias are positioned above and completely within the face of the conductive through vias, thereby preventing the conductive vias from contacting the silicon material of the interposer, and thus effectively improving the quality of the electrical connections between the conductive vias and the conductive through vias.

### BRIEF DESCRIPTION OF THE DRAWINGS

The present disclosure can be more fully understood by reading the following detailed description of the embodiments, with reference made to the accompanying drawings, wherein:

FIGS. 1 and 1′ are cross-sectional diagrams illustrating the package substrate in accordance with embodiments of the present disclosure;

FIGS. 2A to 2F are cross-sectional diagrams illustrating a method for forming the package substrate in accordance with the present disclosure, wherein FIGS. 2C′ is an enlarged view of a portion of FIG. 2C, and FIG. 2F′ shows another embodiment of FIG. 2F; and

FIG. 2G is a cross-sectional diagram illustrating a subsequent application of the method for forming the package substrate in accordance with the present disclosure.

### DETAILED DESCRIPTION OF THE EMBODIMENTS

The present disclosure is described by the following specific embodiments. Those with ordinary skills in the arts can readily understand the other advantages and functions of the present disclosure after reading this specification.

It should be noted that the structures, proportions, sizes and the like shown in the attached drawings are to be considered only in conjunction with the contents of this specification to facilitate understanding and reading of those skilled in the art, and are not intended to limit the scope of present disclosure, thus they do not hold any real technically significance, and any changes or modifications in the structures, the proportions, the sizes and the like should fall within the scope of the technical contents disclosed in the present disclosure as long as they do not affect the effects and the objectives achieved by the present disclosure. Meanwhile, terms such as “above”, “first”, “second” and “a/an” used in this specification are used for illustration purposes only, and are not intended to limit the scope of the present disclosure in any way, any changes or modifications of the relative relationships of elements are therefore to be construed as with the scope of the present disclosure as long as there is no changes to the technical contents.

The term “conductive through vias” used herein refers to conductive elements formed in a substrate, for example, in the interposer described in this specification. The shape of the conductive through vias may be for example, columnar as shown in the diagrams herein.

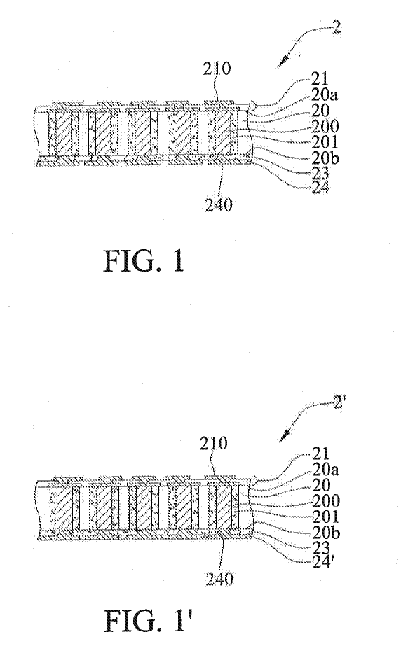

Referring to FIG. 1, a package substrate 2 in accordance with an embodiment of the present disclosure is shown. As shown in FIG. 1, the package substrate 2 includes an interposer 20, a second insulating layer 23, and a circuit layer 24.

The interposer 20 can contain silicon material, and include a first side 20a and a second side 20b opposing the first side 20a, and a plurality of conductive through vias 200 penetrating the first side 20a and the second side 20b. A redistribution layer (RDL) is formed on the first side 20a and electrically connected to the various conductive through vias 200. A plurality of electrode pads 210 are provided on the outermost surface of the RDL 21. A first insulating layer 201 is provided on the sidewalls of the conductive through vias 200. The face diameter of the conductive through vias 200 can be less than or equal to 80 μm, and the face diameter formed by the conductive through vias 200 and the first insulating layer 201 together can be more than 80 μm.

The second insulating layer 23 is formed on the second side 20b of the interposer 20. In this embodiment, the first insulating layer 201 and the second insulating layer 23 may be made of, but not limited to, ABF (Ajinomoto build-up film) or other polymer materials.

The circuit layer 24 is formed on the second insulating layer 23, and include conductive vias 240 formed in the second insulating layer 23 and electrically connected to the conductive through vias 200.

In another embodiment, as shown in FIG. 1, a circuit layer 24′ can be embedded into the second insulating layer 23 to reduce the overall height of structure.

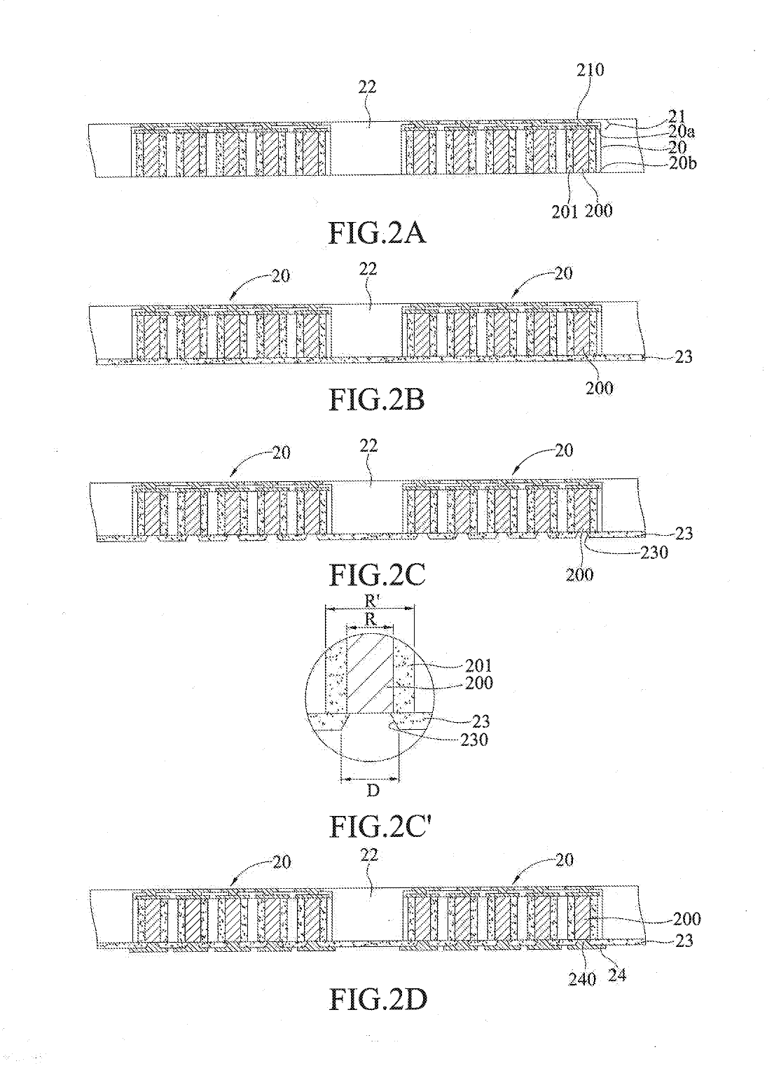

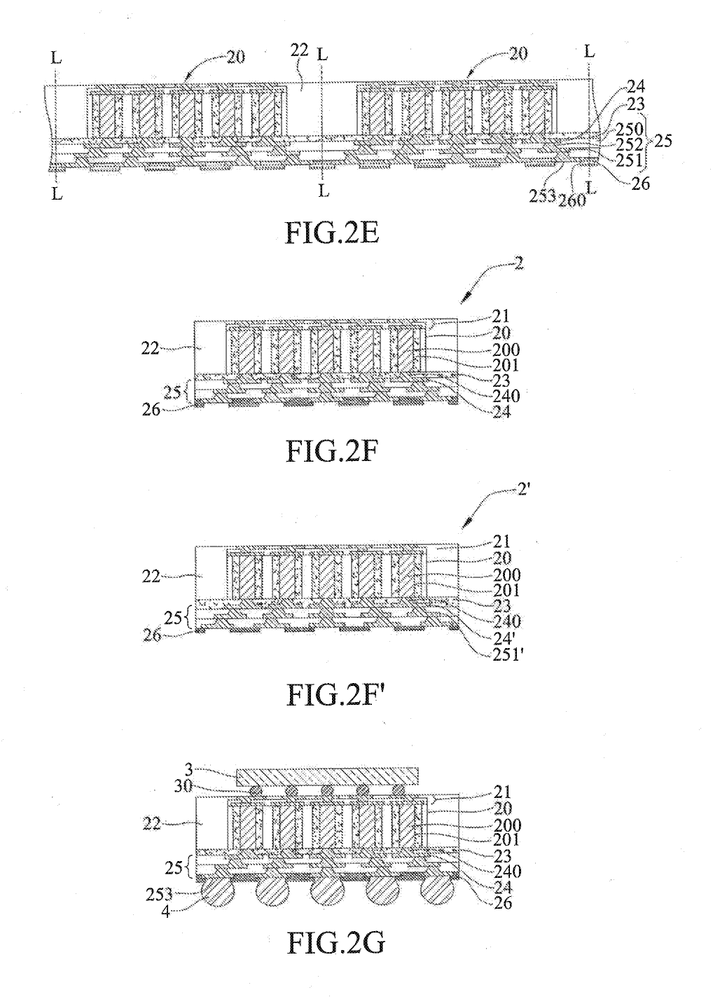

Referring to FIGS. 2A to 2F, a method for forming the aforementioned package substrate 2 is illustrated.

As Shown in FIG. 2A, a molding layer 22 is formed to encapsulate the interposer 20, so that the interposer 20 can be embedded into the molding layer 22, and the RDL 21 is exposed from the molding layer 22.

As shown in FIG. 2B, the second insulating layer 23 is formed on the second side 20b of the interposer 20 and the molding layer 22.

As shown in FIGS. 2C and 2C′, a plurality of vias 230 are formed in the second insulating layer 23 by laser, such that the conductive through vias 200 are exposed from the vias 230.

As shown in FIG. 2D, the circuit layer 24 is formed on the second insulating layer 23, and the conductive vias 240 are formed in the vias 230 to electrically connect the conductive through vias 200 with the circuit layer 24.

In the present embodiment, by increasing he thickness of the insulating layer outside the conductive through vias 200, the face diameter R of the conductive through vias 200 can be not more than 80 μm (e.g. 50 μm). As shown in FIG. 2C′, the face diameter R′ formed by the conductive through vias 200 and the first insulating layer 201 can be more than 80 μm. Therefore, when laser opening is performed, it is easier to align the openings. Therefore, the vias 230 (with a diameter D of 40 μm) can be easily made to be completely within the face of the conductive through vias 200. This enhances the yield of electrical connections between the conductive vias 240 and the conductive through vias 200.

The laser opening technique may use, for example, a IN laser with a drilling diameter of 30 82 m and an alignment accuracy of ±10 μm. In this case, the face diameter R of the conductive through vias 200 may be 50 μm.

Even if the location of a vias 230 is offset, the conductive via 240 will come into contact with the first insulating layer 201 instead of the silicon material of the interposer 20, thereby avoiding poor electrical connection between the conductive vias 240 and the conductive through vias 200.

In addition, a circuit build-up structure 25 can also be manufactured as required, and singulation is subsequently performed. As shown in FIG. 2E, the circuit build-up structure 25 is formed on the second insulating layer 23 and the circuit layer 24, and the circuit build-up structure 25 includes at least a dielectric layer 250, another circuit layer 251 formed on the dielectric layer 250, and additional conductive vias 252 formed in the dielectric layer 250 and electrically connected to the circuit layers 23 and 251.

Next, an insulating protective layer 26 is formed on the circuit build-up structure 25, and a plurality of openings 260 are formed in the insulating protective layer 26 for a portion of circuits of the circuit build-up structure (i.e. the circuit layer 251) exposing therefrom to be used as electrical contact pads 253.

If polymer materials (such as ABF) or the like are used for making the dielectric layer 250 and the first and second insulating layers 201 and 23, then the well-known electroless copper plating technique in the art of circuit board manufacturing can be used to produce the circuit layer 251, thereby significantly reducing the production costs.

As shown in FIG. 2F, the singulation process is performed along cutting lines L shown in FIG. 2E to form the package substrate 2. A package substrate 2′ according to another embodiment is shown in FIG. 2F′. When manufacturing the circuit build-up structure 25, the circuit layer 251 can be embedded into the dielectric layer 250 in order to reduce the height of the whole structure.

In a subsequent application, as shown in FIG. 2G, a semiconductor chip 3 can be mounted above the electrode pads 210 of the RDL 21 through conductive bumps 30 (e.g. solder bumps), and solder balls 4 are formed on each of the electrical contact pads such that the package substrate 2 is joined to a circuit board (not shown) via the solder balls 4.

The above embodiments are only used to illustrate the principles of the present disclosure, and should not be construed as to limit the present disclosure in any way. The above embodiments can be modified by those with ordinary skill in the art without departing from the scope of the present disclosure as defined in the following appended claims.

What is claimed is:

1. A package substrate, comprising
an interposer including a first side, a second side opposing the first side, and at least one conductive through via penetrating from the first side to the second side, wherein a first insulating layer is formed on sidewall of the conductive through via.
a redistribution layer formed on the first side of the interposer and electrically connected to the conductive through via, wherein a face diameter of the conductive through via is not greater than 80 μm, and a face diameter formed by the conductive through via and the first insulating layer is greater than 80 μm;
a second insulating layer formed on the second side of the interposer; and
at least one conductive via formed in the second insulating layer and electrically connected to the conductive through via.

2. The package substrate of claim 1, wherein the interposer includes a silicon material.

3. The package substrate of claim 1, wherein at least one electrode pad is provided at an outer surface of the redistribution layer.

4. The package substrate of claim 1, wherein the first insulating layer is made of an ajinomoto build-up film or a polymer material.

5. The package substrate of claim 1, wherein the second insulating layer is made of an ajinomoto build-up film or a polymer material.

6. The package substrate of claim 1, wherein the face diameter of the conductive through via is 50 μm.

7. The package substrate of claim 1, further comprising a circuit layer formed on the second insulating layer and electrically connected to the conductive via.

8. The package substrate of claim 7, further comprising a circuit build-up structure formed on the second insulating layer and the circuit layer.

9. The package substrate of claim 8, further comprising an insulating protective layer formed on the circuit build-up structure and including a plurality of openings for a portion of circuits of the circuit build-up structure to he exposed therefrom, so as for the exposed portion of the circuits of the circuit build-up structure to be used as electrical contact pads.

10. The package substrate of claim 1, further comprising a molding layer for encapsulating the interposer.

11. The package substrate of claim 10, wherein the molding layer exposes the redistribution layer.

12. A method for forming a package substrate, comprising:
providing an interposer including a first side, a second side opposing the first side, and at least one conductive through via penetrating from the first side to the second side;
forming a redistribution layer on the first side of the interposer, wherein the redistribution layer is electrically connected to the conductive through via;
forming a first insulating layer on sidewall of the conductive through via, wherein the face diameter of the conductive through via is not greater than 80 μm, and the face diameter formed by the conductive through via and the first insulating layer is greater than 80 μm;
forming a second insulating layer on the second side of the interposer;
forming at least one via in the second insulating layer by laser for exposing the conductive through via; and
forming a conductive via in the via electrically connected to the conductive through via.

13. The method of claim 12, wherein the interposer includes a silicon material.

14. The method of claim 12, wherein at least one electrode pad is provided at an outer surface of the redistribution layer.

15. The method of claim 12, wherein the first insulating layer is made of an ajinomoto build-up film or a polymer material.

16. The method of claim 12, wherein the second insulating layer is made of an ajinomoto build-up film or a polymer material.

17. The method of claim 12, wherein the face diameter of the conductive through via is 50 μm.

18. The method of claim 12, further comprising forming a circuit layer on the second insulating layer, wherein the circuit layer is electrically connected to the conductive via.

19. The method of claim 18, further comprising forming a circuit build-up structure on the second insulating layer and the circuit layer.

20. The method of claim 19, further comprising forming an insulating protective layer on the circuit build-up structure, wherein the insulating protecting layer includes a plurality of openings for a portion of circuits of the circuit build-up structure to be exposed therefrom, so as for the exposed portion of the circuits of the circuit build-up structure to be used as electrical contact pads.

21. The method of claim 12, further comprising before forming the second insulating layer, forming a molding layer for encapsulating the interposer, so as to embed the interposer in the molding layer.

22. The method of claim 21, wherein the molding layer exposes the redistribution layer.
